(19) United States
(12) Patent Application Publication
(10) Pub. No.: US 2026/0105948 A1
(43) Pub. Date: Apr. 16, 2026

(54) MEMORY DEVICE AND METHOD FOR OPERATING MEMORY DEVICE

(71) Applicant: Samsung Electronics Co., Ltd., Suwon-si (KR)

(72) Inventors: Jiah Jeon, Suwon-si (KR); Minsu Lee, Suwon-si (KR); Jaehoon Jung, Suwon-si (KR)

(21) Appl. No.: 19/272,759

(22) Filed: Jul. 17, 2025

(30) Foreign Application Priority Data
Oct. 11, 2024 (KR) 10-2024-0138508

(51) Int. Cl. G11C 11/4076; G11C 11/4072; G11C 11/4096

(52) U.S. Cl. CPC G11C 11/4076; G11C 11/4072; G11C 11/4096

(57) ABSTRACT

A memory device includes an active control circuit configured to generate an active progress signal based on an active signal, a counter circuit configured to receive an internal clock signal, the active progress signal, and internal clock signal information, count the internal clock signal, and output a counting completion signal based on the counting result of the internal clock signal and the internal clock signal information, and a counter block circuit configured to output a counting stop signal to stop the counting operation of the counter circuit based on the counting completion signal.

### CROSS-REFERENCE TO RELATED APPLICATION

This application claims priority to Korean Patent Application No. 10-2024-0138508 filed in the Korean Intellectual Property Office on Oct. 11, 2024, the contents of which are incorporated herein by reference in its entirety.

### BACKGROUND

A memory device, such as a dynamic random access memory (DRAM), may include a memory cell array for storing data. In general, the arrangement of the memory cell array is implemented as a lattice having rows and columns, such that a cell can be accessed to read or write data by specifying an address including a row and a column. A DRAM may include a plurality of memory cell arrays, and a unit including at least some of the plurality of memory cell arrays may be defined as a bank.

Meanwhile, a counter circuit corresponding to each bank performs an operation of counting a clock signal for the time of a row address strobe (tRAS) in an active section for the corresponding bank, but keeps counting the clock signal even after the tRAS ends, resulting in a power consumption problem.

Further, with the recent advent of high bandwidth memories (HBMs), the numbers of banks which are included in memory devices have further increased, and accordingly, designing counter circuits in a limited space in a memory device is also one of the problems to be solved.

### SUMMARY

In general, the present disclosure is directed toward a memory device with improved power usage and a method for operating the memory device, in which the memory device has a space inside a chip that is efficiently usable.

According to some implementations, the present disclosure is directed to a memory device that includes an active control circuit configured to generate an active progress signal on the basis of an active signal, a counter circuit configured to receive an internal clock signal, the active progress signal, and internal clock signal information, count the internal clock signal, and output a counting completion signal on the basis of the counting result of the internal clock signal and the internal clock signal information, and a counter block circuit configured to output a counting stop signal for stopping the counting operation of the counter circuit, on the basis of the counting completion signal.

According to some implementations, the present disclosure is directed to a memory device that includes a first memory bank disposed inside a first memory cell die, a second memory bank disposed inside the first memory cell die so as to be spaced apart from the first memory bank in a first direction, a plurality of through-silicon vias positioned in a region between the first memory bank and the second memory bank inside the first memory cell die, and a first count circuit positioned between the plurality of through-silicon vias inside the first memory cell die, and configured to receive a first active signal for activating the first memory bank and an internal clock signal, count the internal clock signal, and block the internal clock signal when the counting of the internal clock signal is completed.

According to some implementations, the present disclosure is directed to a method for operating a memory device that includes a step of generating an active progress signal on the basis of an active signal, a step of receiving an internal clock signal, the active progress signal, and internal clock signal information, a step of counting the internal clock signal, a step of outputting a counting completion signal on the basis of the counting result of the internal clock signal and the internal clock signal information, and a step of outputting a counting stop signal for stopping the counting operation, on the basis of the counting completion signal.

### BRIEF DESCRIPTION OF THE DRAWINGS

Example implementations will be more clearly understood from the following detailed description, taken in conjunction with the accompanying drawings.

FIG. 1 is a block diagram illustrating an example of a memory system according to some implementations.

FIG. 2 is a block diagram illustrating an example of a memory controller according to some implementations.

FIG. 3 is a block diagram illustrating an example of a memory device according to some implementations.

FIG. 4 is a block diagram illustrating an example of a memory device according to some implementations.

FIG. 5 is a timing chart illustrating an example of an operation of a memory device according to some implementations.

FIG. 6 is a flow chart illustrating an example of an operation of a memory device according to some implementations.

FIG. 7 is a flow chart illustrating an example of an operation of a memory device according to some implementations.

FIG. 8 is a drawing illustrating an example of a memory device according to some implementations.

FIG. 9 is a drawing illustrating an example of a memory device according to some implementations.

FIG. 10 is a drawing illustrating an example of a memory device according to some implementations.

FIG. 11 is a drawing illustrating an example of a memory device according to some implementations.

FIG. 12 is a drawing illustrating an example of a memory device according to some implementations.

FIG. 13 is a perspective view illustrating an example of a semiconductor device according to some implementations.

FIG. 14 is a perspective view illustrating an example of a semiconductor device according to some implementations.

FIG. 15 is a schematic block diagram illustrating an example of a computing device according to some implementations.

### DETAILED DESCRIPTION

Hereinafter, example implementations will be explained in detail with reference to the accompanying drawings.

The drawings and description are to be regarded as illustrative in nature and not restrictive. Like reference numerals designate like elements throughout the specification. In the flow charts described with reference to the drawings, the order of operations may be changed, and several operations may be combined, and an operation may be divided, and some operations may not be performed.

Further, expressions written in the singular forms can be comprehended as the singular forms or plural forms unless clear expressions such as “a”, “an”, or “single” are used. Terms including an ordinal number, such as first and second, are used for describing various constituent elements, but the constituent elements are not limited by the terms. These terms are used only to discriminate one constituent element from other constituent elements.

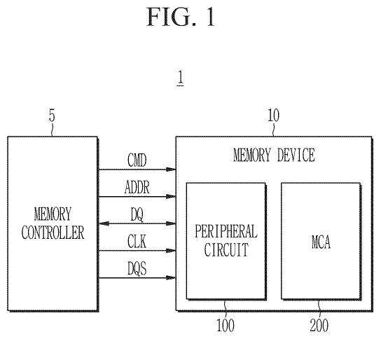

FIG. 1 is a block diagram illustrating an example of a memory system according to some implementations. In FIG. 1, a memory system 1 may include a memory controller 5 and a memory device 10. The memory controller 5 may generally control the operation of the memory system 1. The memory controller 5 may control general data exchange between an external host and the memory device 10. For example, the memory controller 5 may control the memory device 10 to write data or read data in response to a request of the host.

Also, the memory controller 5 may apply operation commands for controlling the memory device 10, to control the operation of the memory device 10. The memory device 10 may be a DRAM, a double data rate 5 (DDR5), a synchronous DRAM (SDRAM), or a DDR6 SDRAM including volatile memory cells; however, the exemplary embodiment is not necessarily limited thereto.

The memory controller 5 may include a processor that controls the overall operation of the memory controller 5, and the memory controller 5 may control the memory device 10 on the basis of the operation of a processor. The memory controller 5 may transmit a clock signal CLK (or a command clock signal), a command CMD, and an address ADDR to the memory device 10. When the memory controller 5 transmits a data signal DQ to the memory device 10 or receives a data signal DQ from the memory device 10, it may exchange data strobe signal DQS with the memory device 10. The address ADDR may accompany a command CMD, and in the present disclosure, an address ADDR may be referred to as an access address.

The memory device 10 may include a peripheral circuit 100, and a memory cell array (MCA) 200 for storing data. The peripheral circuit 100 may control the operation of the memory cell array 200.

The memory cell array 200 may include a plurality of bank arrays, and each bank array may include a plurality of sub memory arrays including a plurality of volatile memory cells.

Further, each bank array may be divided into a plurality of row blocks, by row block identification bits which includes some bits of row addresses, and each row block may include a plurality of sub memory arrays arranged in one direction.

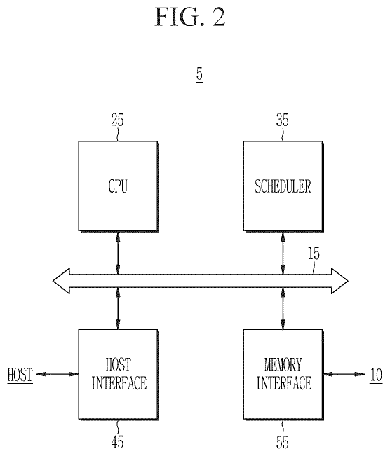

FIG. 2 is a block diagram illustrating an example of a memory controller according to some implementations. In FIG. 2, the memory controller 5 may include a central processing unit (CPU) 25, a scheduler 35, a host interface 45, and a memory interface 55 that are connected through a bus 15.

The CPU 25 may control the overall operation of the memory controller 5. The CPU 25 may control the scheduler 35, the host interface 45, and the memory interface 55.

The scheduler 35 may manage scheduling and transmission of sequences of commands generated in the memory controller 5. Specifically, the scheduler 35 may provide an active command and the following command to the memory device 10 through the memory interface 55.

The host interface 45 may perform interfacing with the host. The memory interface 55 may perform interfacing with the memory device 10.

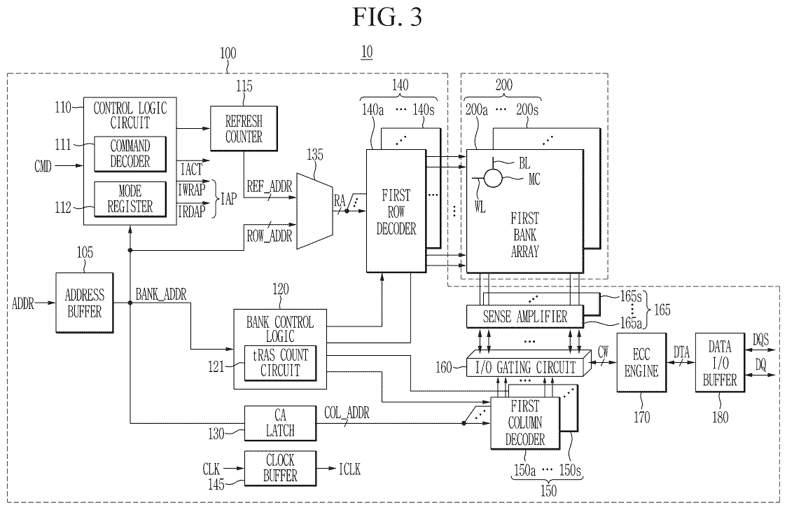

FIG. 3 is a block diagram illustrating an example of a memory device according to some implementations. In FIG. 3, the memory device 10 may include the peripheral circuit 100 and the memory cell array 200.

The peripheral circuit 100 may include an address register 105, a control logic circuit 110, a refresh counter 115, a bank control logic 120, a column address (CA) latch 130, a row address multiplexer 135, a row decoder 140, a clock buffer 145, a column decoder 150, an input/output gating circuit (I/O gating circuit) 160, a sense amplifier 165, an ECC engine 170, and a data input/output circuit (data I/O circuit) 180.

The memory cell array 200 may include first to 16^{th} bank arrays 200a to 200s. The row decoder 140 may include first to 16^{th} row decoders 140a to 140s connected to the first to 16^{th} bank arrays 200a to 200s, respectively, and the column decoder 150 may include first to 16^{th} column decoders 150a to 150s connected to the first to 16^{th} bank arrays 200a to 200s, respectively, and the sense amplifier 165 may include first to 16^{th} sense amplifiers 165a to 165s connected to the first to 16^{th} bank arrays 200a to 200s, respectively.

The first to 16^{th} bank arrays 200a to 200s, the first to 16^{th} sense amplifiers 165a to 165s, the first to 16^{th} column decoders 150a to 150s, and the first to 16^{th} row decoders 140a to 140s may operate as first to 16^{th} banks. Each of the first to 16^{th} bank arrays 200a to 200s may include a plurality of word lines WL, a plurality of bit lines BTL, and a plurality of memory cells MC which is disposed at the intersections of the word lines WL and the bit lines BTL. Meanwhile, although it is shown in FIG. 3 that the memory device 10 includes sixteen banks, the present disclosure is not necessarily limited thereto, and the number of banks may be changed at any time depending on exemplary embodiments.

Each of the first to 16^{th} bank arrays 200a to 200s may include a plurality of memory cells MC which is a plurality of volatile memory cells for storing data. Further, each of the first to 16^{th} bank arrays 200a to 200s may include a plurality of sub memory arrays, and the plurality of sub memory arrays may be divided into a plurality of row blocks by row block identification bits of some bits of row addresses. Each row block may include a plurality of sub memory arrays which is arranged in one direction.

The control logic circuit 110 may control the operation of the memory device 10. For example, the control logic circuit 110 may generate control signals such that the memory device 10 performs a write operation or a read operation.

Specifically, the control logic circuit 110 may include a command decoder 111 which decodes a received command CMD, and a mode register 112 for setting the operation mode of the memory device 10.

The command decoder 111 may generate control signals corresponding to a command CMD by decoding a chip selection signal, a command/address signal, and the like. In some implementations, the command decoder 111 may generate an active signal IACT, a write with auto-precharge signal IWRAP, and a read with auto-precharge signal IRDAP by decoding a command CMD. Further, the command decoder 111 may generate a control signal to control the input/output gating circuit 160 and the ECC engine 170 by decoding a command CMD.

The mode register 112 may store a code which is provided from the address register 105. The number, addresses, code size, and the like of mode registers 112 may be defined in JEDEC standards. The memory controller 5 may issue a mode register write command CMD and a code to change values stored in the mode register 112 and set the operation condition, operation mode, and the like of the memory device 10.

The address register 105 may receive an address ADDR including a bank address BANK_ADDR, a row address ROW_ADDR, and a column address COL_ADDR from the memory controller (5 in FIG. 1). The address register 105 may provide the received bank address BANK_ADDR to the bank control logic 120, provide the received row address ROW_ADDR to the row address multiplexer 135, and provide the received column address COL_ADDR to the column address latch 130.

The bank control logic 120 may generate a bank control signal in response to the bank address BANK_ADDR. In response to the bank control signal, a row decoder corresponding to the bank address BANK_ADDR among the first to 16^{th} row decoders 140a to 140s may be activated, and a column decoder corresponding to the bank address BANK_ADDR among the first to 16^{th} column decoders 150a to 150s may be activated.

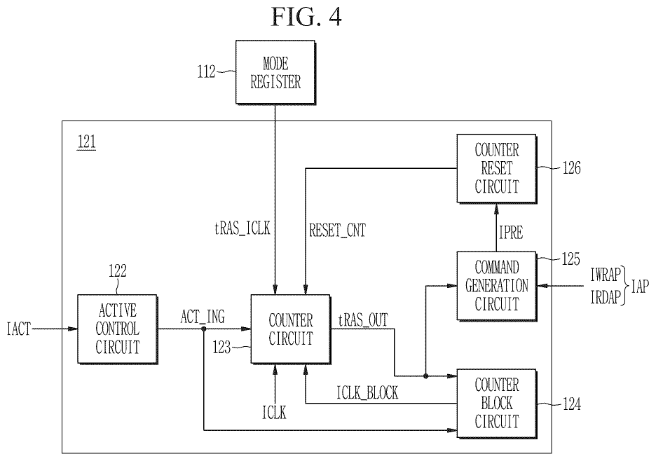

Further, the bank control logic 120 may include a plurality of tRAS count circuits 121. The plurality of tRAS count circuits 121 may count tRAS periods corresponding to the first to 16^{th} bank arrays 200a to 200s on the basis of a bank address BANK_ADDR, and an active signal IACT and an auto-precharge signal IAP from the control logic circuit 110. A tRAS count circuit 121 corresponding to the bank address BANK_ADDR among the plurality of tRAS count circuits 121 may receive the active signal IACT and the auto-precharge signal IAP, count tRAS sections, and stop the counting operation when the tRAS section counting is completed. A tRAS section may be determined on the basis of the value of a code stored in the mode register 112. Details will be described with reference to FIG. 4 and the subsequent drawings.

The row address multiplexer 135 may receive a row address ROW_ADDR from the address register 105, and receive a refresh row addresses REF_ADDR from the refresh counter 115. The row address multiplexer 135 may selectively output the row address ROW_ADDR or the refresh row address REF_ADDR as a row address RA. The row address RA output from the row address multiplexer 135 may be applied to each of the first to 16^{th} row decoders 140a to 140s.

A row decoder activated among the first to 16^{th} row decoders 140a to 140s by the bank control logic 120 may decode the row address RA output from the row address multiplexer 135 to activate a word line corresponding to the row address. Each of the first to 16^{th} row decoders 140a to 140s may include a plurality of sub word line drivers. For example, a sub word line driver in the activated row decoder may apply a word line driving voltage to the word line corresponding to the row address.

The column address latch 130 may receive a column address COL_ADDR from the address register 105, and temporarily store the received column address COL_ADDR. Also, the column address latch 130 may gradually increase the received column address COL_ADDR in a burst mode. The column address latch 130 may apply the column address COL_ADDR temporarily stored or gradually increased, to each of the first to 16^{th} column decoders 150a to 150s.

The clock buffer 145 may receive the clock signal CLK from the memory controller (5 in FIG. 1). The clock buffer 145 may buffer the clock signal CLK to generate an internal clock signal ICLK. The internal clock signal ICLK may be provided to constituent elements for processing a command CMD and an address ADDR. For example, the internal clock signal ICLK may be provided to the command decoder 111 and the tRAS count circuit 121.

A column decoder activated among the first to 16^{th} column decoders 150a to 150s by the bank control logic 120 may activate a sense amplifier corresponding to a bank address BANK_ADDR and a column address COL_ADDR through a corresponding input/output gating circuit 160.

The input/output gating circuit 160 may include an input data mask logic, a read data latch for storing a code word output from the first to 16^{th} bank arrays 200a to 200s, and write drivers for writing data in the first to 16^{th} bank arrays 200a to 200s, together with circuits for gating input/output data.

A code word CW read from one bank array of the first to 16^{th} bank arrays 200a to 200s may be sensed by a sense amplifier corresponding to the one bank array, and be stored in the read data latch. The code word CW stored in the read data latch may be subjected to ECC decoding by the ECC engine 170, and be provided as data DTA to the data input/output circuit 180, and the data input/output circuit 180 may convert the data DTA into a data signal DQ and provide the data signal DQ together with a strobe signal DQS to the memory controller (5 in FIG. 1).

The data signal DQ to be written in one bank array of the first to 16^{th} bank arrays 200a to 200s may be received together with the strobe signal DQS by the data input/output circuit 180. The data input/output circuit 180 may convert the data signal DQ into the data DTA and provide the data to the ECC engine 170, and the ECC engine 170 may generate parity data (or a parity bit) on the basis of the data DTA and provide a code word CW including the data DTA and the parity data to the input/output gating circuit 160. The input/output gating circuit 160 may write the code word CW in a target page of the one bank array through the write drivers.

During a write operation, the data input/output circuit 180 may convert a data signal DQ into data DTA and provide the data to the ECC engine 170, and during a read operation, it may convert data provided from the ECC engine 170 into a data signal DQ and provide the data signal DQ and a strobe signal DQS to the memory controller (5 in FIG. 1).

The ECC engine 170 may perform ECC encoding on data DTA and ECC decoding on a code word CW on the basis of a control signal which is provided from the control logic circuit 110.

FIG. 4 is a block diagram illustrating an example of a memory device according to some implementations. In FIG. 4, the tRAS count circuit 121 may include an active control circuit 122, a counter circuit 123, a counter block circuit 124, a command generating circuit 125, and a counter reset circuit 126. The tRAS count circuit 121 may operate on the basis of a corresponding bank address (BANK_ADDR in FIG. 3).

The active control circuit 122 may receive an active signal IACT from the outside (for example, the command decoder 111 of FIG. 3). The active control circuit 122 may generate an active progress signal ACT_ING on the basis of the active signal IACT. The active progress signal ACT_ING may be a signal for causing the counter circuit 123 to start an operation of counting the internal clock signal ICLK. The active control circuit 122 may provide the active progress signal ACT_ING to the counter circuit 123 and the counter block circuit 124.

The counter circuit 123 may receive the internal clock signal ICLK, the active progress signal ACT_ING, and internal clock signal information tRAS_ICLK. For example, the counter circuit 123 may receive the internal clock signal ICLK from the clock buffer (145 in FIG. 3), and may receive the active progress signal ACT_ING from the active control circuit 122, and may receive the internal clock signal information tRAS_ICLK from the mode register 112.

Specifically, the mode register 112 may store information on a tRAS section as a code, and output the code as the internal clock signal information tRAS_ICLK to the counter circuit 123. The mode register 112 may output a binary value based on the frequency of the internal clock signal of the tRAS section as the internal clock signal information tRAS_ICLK to the counter circuit 123.

The counter circuit 123 may receive the internal clock signal ICLK, the active progress signal ACT_ING, and the internal clock signal information tRAS_ICLK, and count the internal clock signal ICLK for the tRAS section of the active section for the bank corresponding to the bank address BANK_ADDR.

Specifically, the counter circuit 123 may count the internal clock signal ICLK from when receiving the active progress signal ACT_ING. The counter circuit 123 may count the internal clock signal ICLK by the value of the internal clock signal information tRAS_ICLK, and output a counting completion signal tRAS_OUT. In other words, the counter circuit 123 may output the counting completion signal tRAS_OUT indicating that the tRAS section has ended. The counter circuit 123 may output the counting completion signal tRAS_OUT to the counter block circuit 124 and the command generating circuit 125.

The counter block circuit 124 may output a counting stop signal ICLK_BLOCK on the basis of the counting completion signal tRAS_OUT output from the counter circuit 123. The counter block circuit 124 may provide the counting stop signal ICLK_BLOCK to the counter circuit 123.

The counter circuit 123 may stop the operation of counting the internal clock signal ICLK on the basis of the counting stop signal ICLK_BLOCK provided from the counter block circuit 124.

According to a comparative example, in an active section, a counter circuit counts an internal clock signal even after a tRAS section ends, resulting in a problem in which a counter consumes unnecessary power. Unlike this, in the memory device, when the counter circuit 123 completes the operation of counting the internal clock signal for the tRAS section, the counting stop signal ICLK_BLOCK output from the counter block circuit 124 in response to that causes the counter circuit 123 to stop the operation of counting the internal clock signal ICLK. Accordingly, it is possible to solve the problem of unnecessary power consumption.

The command generating circuit 125 may receive the counting completion signal tRAS_OUT from the counter circuit 123. The command generating circuit 125 may receive an auto-precharge signal IAP including a write with auto-precharge signal IWRAP and a read with auto-precharge signal IRDAP from the outside (for example, the command decoder 111).

The command generating circuit 125 may receive the counting completion signal tRAS_OUT, and receive the auto-precharge signal IAP. The command generating circuit 125 may generate an internal precharge signal IPRE for performing a precharge operation on a corresponding one of the first to 16^{th} bank arrays (200a to 200s in FIG. 3), on the basis of the counting completion signal tRAS_OUT and the auto-precharge signal IAP. The command generating circuit 125 may provide the internal precharge signal IPRE to the counter reset circuit 126 and a corresponding one of the first to 16^{th} bank arrays (200a to 200s in FIG. 3).

The counter reset circuit 126 may output a reset signal RESET_CNT on the basis of the internal precharge signal IPRE. The counter reset circuit 126 may output the reset signal RESET_CNT to the counter circuit 123 to reset the counter circuit 123 to an initial state for counting the internal clock signal ICLK.

When the precharge operation is completed in response to the internal precharge signal IPRE, the following active progress signal ACT_ING may be provided to the tRAS count circuit 121. The active progress signal ACT_ING may be provided to the counter circuit 123 as well as to the counter block circuit 124, as described above.

When the counter block circuit 124 receives the following active progress signal ACT_ING, it may not output the counting stop signal ICLK_BLOCK to the counter circuit 123. In some implementations, the counter block circuit 124 may change the signal level of the counting stop signal ICLK_BLOCK to be output to the counter circuit 123, and output the counting stop signal to the counter circuit 123.

Accordingly, the counter circuit 123 may perform an operation of counting the internal clock signal ICLK for the tRAS section of the next active section, on the basis of the active progress signal ACT_ING and the internal clock signal information tRAS_ICLK.

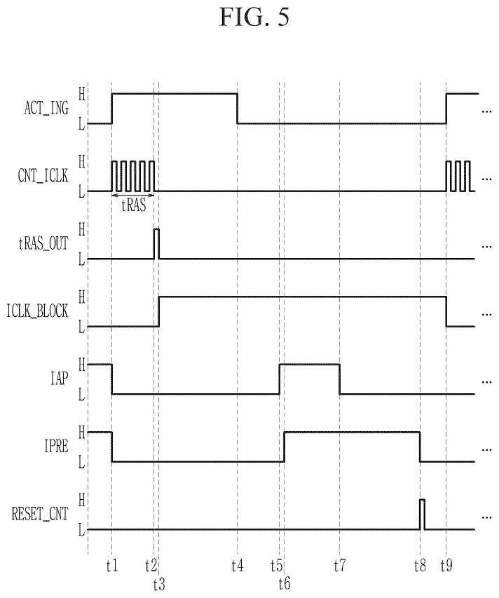

FIG. 5 is a timing chart illustrating an example of an operation of a memory device according to some implementations. In FIG. 5, at a first time point t1, the active progress signal ACT_ING may transition from a first level L to a second level H. The first time point t1 may refer to the time point when the active section starts. In other words, the first time point t1 may refer to the time point when the counter circuit (123 in FIG. 4) starts an operation of counting the internal clock signal (reference symbol “ICLK” in FIG. 4). Meanwhile, hereinafter, the first level L may refer to logical 0, and the second level H may refer to logical 1.

In response to the transition of the active progress signal ACT_ING from the first level L to the second level H at the first time point t1, the counter circuit 123 may count the internal clock signal ICLK. Specifically, the counter circuit 123 may count the clock signal on the basis of the received internal clock signal information (tRAS_ICLK in FIG. 4). For example, the counter circuit 123 may count the internal clock signal ICLK a predetermined number of times for the tRAS section, like an internal clock counting signal CNT_ICLK shown in FIG. 5.

At a second time point t2, the counter circuit 123 may complete the operation of counting the internal clock signal ICLK for the tRAS section. When completing the counting operation, the counter circuit 123 may output the counting completion signal tRAS_OUT. The counting completion signal tRAS_OUT may be provided in such a pulse form that it transitions from the first level L to the second level H at the second time point t2 and transitions from the second level H back to the first level L at a third time point t3.

At the third time point t3, the counter block circuit (124 in FIG. 4) may output the counting stop signal ICLK_BLOCK on the basis of the counting completion signal tRAS_OUT received from the counter circuit 123. The counting stop signal ICLK_BLOCK may transition from the first level L to the second level H at the third time point t3, and the counting stop signal ICLK_BLOCK at the second level H may be provided to the counter circuit 123.

The counter circuit 123 may stop the clock signal counting operation on the basis of the counting stop signal ICLK_BLOCK at the second level H provided to the counter circuit 123. Accordingly, as shown in FIG. 5, even when the active progress signal ACT_ING is at the second level H and the internal precharge signal IPRE is not received, the counter circuit 123 stops the operation of counting the internal clock signal ICLK, thereby capable of reducing unnecessary power consumption.

At a fourth time point t4, the active progress signal ACT_ING may transition from the second level H to the first level L. In other words, the fourth time point t4 may correspond to the time point when the active section ends.

In response to the end of the active section, the auto-precharge signal IAP may be provided. Specifically, the auto-precharge signal IAP may be provided to the command generating circuit (125 in FIG. 4), and at a fifth time point t5, the auto-precharge signal IAP may transition from the first level L to the second level H.

The command generating circuit 125 may generate the internal precharge signal IPRE on the basis of the received auto-precharge signal IAP. The internal precharge signal IPRE may transition from the first level L to the second level H at a sixth time point t6 following the fifth time point t5.

At a seventh time point t7, the auto-precharge signal IAP may transition from the second level H to the first level L. Based on the transitioned auto-precharge signal IAP, the internal precharge signal IPRE which is output from the command generating circuit 125 may transition from the second level H to the first level L at an eighth time point t8 following the seventh time point t7. In other words, the eighth time point t8 may refer to the time point when the precharge operation is completed.

In response to the transition of the internal precharge signal IPRE from the second level H to the first level L at the eighth time point t8, the counter reset circuit (126 in FIG. 4) may output the reset signal RESET_CNT. The reset signal RESET_CNT may be provided in such a pulse form that it transitions from the first level L to the second level H at the eighth time point t8 and immediately thereafter transitions from the second level H back to the first level L. The counter reset circuit 126 may provide the reset signal RESET_CNT to the counter circuit 123.

At a ninth time point t9, the following active progress signal ACT_ING may be provided. In other words, at the ninth time point t9, the active progress signal ACT_ING may transition from the first level L back to the second level H.

The active progress signal ACT_ING may be provided to the counter circuit 123 and the counter block circuit 124. The counter block circuit 124 may output the counting stop signal ICLK_BLOCK having transitioned from the second level H to the first level L, in response to the received active progress signal ACT_ING.

The counter circuit 123 may restart the operation of counting the internal clock signal ICLK on the basis of the received active progress signal ACT_ING and the internal clock signal information tRAS_ICLK. In other words, the operation from the ninth time point t9 may be substantially identical to the operation which is performed from the first time point t1 to the eighth time point t8.

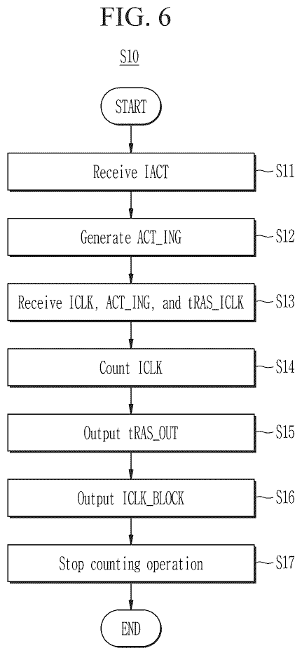

FIG. 6 is a flow chart illustrating an example of an operation of a memory device according to some implementations. In FIG. 6, a method (S10) for operating the memory device may include a step of receiving the active signal IACT (S11). Specifically, the active control circuit (122 in FIG. 4) may receive the active signal IACT output from the command decoder (111 in FIG. 3).

The method (S10) for operating the memory device may include a step of generating the active progress signal ACT_ING (S12). Specifically, the active control circuit 122 may generate the active progress signal ACT_ING on the basis of the received active signal IACT.

The method (S10) for operating the memory device may include a step of receiving the internal clock signal ICLK, the active progress signal ACT_ING, and the internal clock signal information tRAS_ICLK (S13). Specifically, the counter circuit (123 in FIG. 4) may receive the internal clock signal ICLK from the clock buffer (145 in FIG. 3), may receive the active progress signal ACT_ING from the active control circuit 122, and may receive the internal clock signal information tRAS_ICLK from the mode register (112 in FIG. 3).

The method (S10) for operating the memory device may include a step of counting the internal clock signal ICLK (S14). Specifically, the counter circuit 123 may count the internal clock signal ICLK for a specific section of the active section, i.e., the tRAS section, on the basis of the received active progress signal ACT_ING and the internal clock signal information tRAS_ICLK.

The method (S10) for operating the memory device may include a step of outputting the counting completion signal tRAS_OUT (S15). Specifically, the counter circuit 123 may output the counting completion signal tRAS_OUT when the operation of counting the internal clock signal ICLK for the tRAS section of the active section is completed.

The method (S10) for operating the memory device may include a step of outputting the counting stop signal (S16). Specifically, the counter block circuit (124 in FIG. 4) may output the counting stop signal ICLK_BLOCK on the basis of the counting completion signal tRAS_OUT received from the counter circuit 123.

The method (S10) for operating the memory device may include a step of stopping the clock signal counting operation (S17). Specifically, the counter circuit 123 may stop the operation of counting the clock signal on the basis of the counting stop signal ICLK_BLOCK received from the counter block circuit 124.

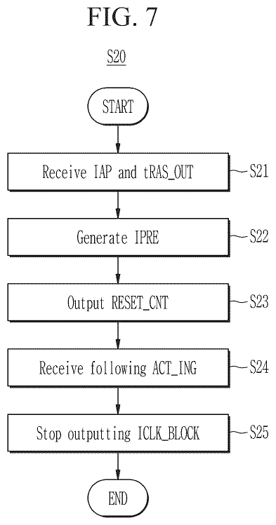

FIG. 7 is a flow chart illustrating an example of an operation of a memory device according to some implementations. In FIG. 7, a method (S20) for operating the memory device may include a step of receiving the auto-precharge signal IAP and the counting completion signal tRAS_OUT (S21). Specifically, the command generating circuit (125 in FIG. 4) may receive the auto-precharge signal IAP including the write with auto-precharge signal (IWRAP in FIG. 4) and the read with auto-precharge signal (IRDAP in FIG. 4) from the outside (for example, the command decoder 111 in FIG. 3), and may receive the counting completion signal tRAS_OUT from the counter circuit (123 in FIG. 4).

The method (S20) for operating the memory device may include a step of generating the internal precharge signal IPRE (S22). Specifically, the command generating circuit 125 may generate the internal precharge signal IPRE for performing a precharge operation, on the basis of the auto-precharge signal IAP and the counting completion signal tRAS_OUT received.

The method (S20) for operating the memory device may include a step of outputting the reset signal RESET_CNT (S23). Specifically, the counter reset circuit (126 in FIG. 4) may output the reset signal RESET_CNT on the basis of the internal precharge signal IPRE received from the command generating circuit 125. The counter reset circuit 126 may provide the reset signal RESET_CNT to the counter circuit 123, and the counter circuit 123 may be reset to the initial state for performing a counting operation on the basis of the reset signal RESET_CNT.

The method (S20) for operating the memory device may include a step of receiving the following active progress signal ACT_ING (S24). Specifically, the active control circuit (122 in FIG. 4) may generate an active progress signal ACT_ING corresponding to the following active signal IACT, and the counter circuit 123 and the counter block circuit (124 in FIG. 4) may receive the active progress signal ACT_ING.

The method (S20) for operating the memory device may include a step of stopping outputting the counting stop signal ICLK_BLOCK (S25). Specifically, the counter block circuit 124 may stop outputting the counting stop signal ICLK_BLOCK to the counter circuit 123, on the basis of the received active progress signal ACT_ING.

The method for operating the memory device shown in FIGS. 6 and 7 may be performed in response to a change in the level of a signal, as shown in FIG. 5. For example, in the method (S10) of FIG. 6 for operating the memory device, the step of counting the internal clock signal ICLK (S14) may be performed on the basis of receiving the active progress signal ACT_ING having transitioned from the first level L to the second level H as shown in FIG. 5.

Further, in the method (S10) of FIG. 6 for operating the memory device, the step of outputting the counting stop signal ICLK_BLOCK (S16) may include a step of outputting the counting stop signal ICLK_BLOCK having transitioned from the first level L to the second level H, in response to reception of the counting completion signal tRAS_OUT as shown in FIG. 5.

Furthermore, in the method (S20) of FIG. 7 for operating the memory device, the step of stopping outputting the counting stop signal ICLK_BLOCK (S25) may be performed on the basis of a change of the counting stop signal ICLK_BLOCK from the second level H to the first level L as shown in FIG. 5.

Meanwhile, although it has been described for ease of explanation that the method (S20) of FIG. 7 for operating the memory device is performed subsequent to the method (S10) of FIG. 6 for operating the memory device, the method (S20) of FIG. 7 for operating the memory device may be performed, and the method (S10) of FIG. 6 for operating the memory device may be performed subsequent to that. In other words, the methods (S10 and S20) of FIGS. 6 and 7 for operating the memory device may be performed alternately with each other.

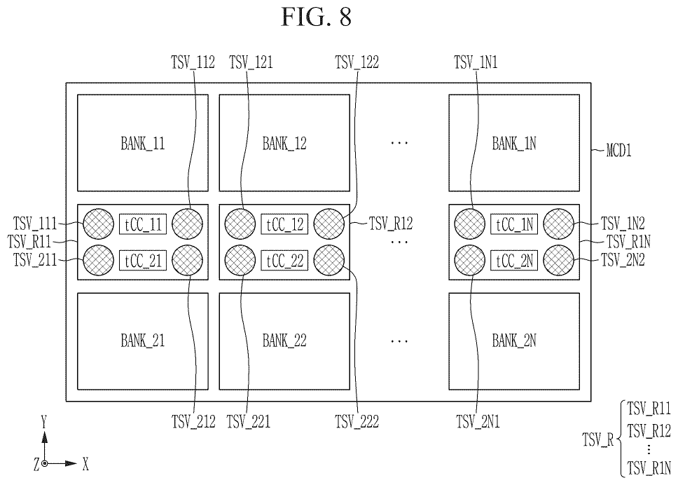

FIG. 8 is a drawing illustrating an example of memory device according to some implementations. In FIG. 8, a first memory cell die MCD1 included in the memory device may include a plurality of banks (memory banks) of a first group that is arranged in a first direction X, and a plurality of banks of a second group that is spaced apart from the banks of the first group in a second direction Y and is arranged in the first direction X.

Specifically, the plurality of banks of the first group may include an 11-th bank BANK_11 to a 1N-th bank BANK_1N, and the plurality of banks of the second group may include a 21-th bank BANK_21 to a 2N-th bank BANK_2N.

The 11-th bank BANK_11 and the 21-th bank BANK_21 may be disposed at the same position in the first direction X so as to be spaced apart in the second direction Y, and the 12-th bank BANK_12 and the 22-th bank BANK_22 may also be disposed at the same position in the first direction X so as to be spaced apart in the second direction Y. In other words, the 1N-th bank BANK_1N and the 2N-th bank BANK_2N may be disposed at the same position in the first direction X so as to be spaced apart in the second direction Y.

All of the separation distance between the 11-th bank BANK_11 and the 21-th bank BANK_21, the separation distance between the 12-th bank BANK_12 and the 22-th bank BANK_22, and the separation distance between the 1N-th bank BANK_1N and the 2N-th bank BANK_2N may be substantially the same. Between banks disposed at the same position in the first direction, a through-silicon via region TSV_R where a through-silicon via TSV is disposed may be disposed.

Specifically, an 11-th through-silicon via region TSV_R11 may be disposed in the separation region between the 11-th bank BANK_11 and the 21-th bank BANK_21 in the second direction Y, and similarly, a 12-th through-silicon via region TSV_R12 may be disposed in the separation region between the 12-th bank BANK_12 and the 22-th bank BANK_22 in the second direction Y. In other words, a 1N-th through-silicon via region TSV_R1N may be disposed in the separation region between the 1N-th bank BANK_1N and the 2N-th bank BANK_2N in the second direction Y.

Each through-silicon via region TSV_R may include a plurality of through-silicon vias TSV_111 to TSV2N2. Specifically, the 11-th through-silicon via region TSV_R11 may include a 111-th through-silicon via TSV_111, a 112-th through-silicon via TSV_112, a 211-th through-silicon via TSV_211, and a 212-th through-silicon via TSV_212.

Similarly, the 12-th through-silicon via region TSV_R12 may include a 121-th through-silicon via TSV_121, a 122-th through-silicon via TSV_122, a 221-th through-silicon via TSV_221, and a 222-th through-silicon via TSV_222.

In other words, the 1N-th through-silicon via region TSV_R1N may include a 1N1-th through-silicon via TSV_1N1, a 1N2-th through-silicon via TSV_1N2, a 2N1-th through-silicon via TSV_2N1, and a 2N2-th through-silicon via TSV_2N2.

Each through-silicon via region TSV_R may also include a plurality of tRAS count circuits tCC_11 to tCC_2N. Specifically, the 11-th through-silicon via region TSV_R11 may include an 11-th tRAS count circuit tCC_11 and a 21-th tRAS count circuit tCC_21.

Similarly, a 12-th through-silicon via region TSV_R12 may include a 12-th tRAS count circuit tCC_12 and a 22-th tRAS count circuit tCC_22.

In other words, the 1N-th through-silicon via region TSV_R1N may include a 1N-th tRAS count circuit tCC_1N and a 2N-th tRAS count circuit tCC_2N.

The tRAS count circuits tCC_11 to tCC_2N included in each through-silicon via region TSV_R may perform a counting operation and a counting stop operation on the internal clock signal for the above-described tRAS section with respect to an adjacent bank. For example, the 11-th tRAS count circuit tCC_11 and the 21-th tRAS count circuit tCC_21 included in the 11-th through-silicon via region TSV_R11 may perform the counting operation and the counting stop operation, described above, on the 11-th bank BANK_11 and the 21-th bank BANK_21 adjacent, respectively.

Similarly, the 12-th tRAS count circuit tCC_12 and the 22-th tRAS count circuit tCC_22 included in the 12-th through-silicon via region TSV_R12 may perform the counting operation and the counting stop operation, described above, on the 12-th bank BANK_12 and the 22-th bank BANK_22 adjacent thereto, respectively.

In other words, the 1N-th tRAS count circuit tCC_1N and the 2N-th tRAS count circuit tCC_2N included in the 1N-th through-silicon via region TSV_R1N may perform the counting operation and the counting stop operation, described above, on the 1N-th bank BANK_1N and the 2N-th bank BANK_2N adjacent, respectively.

Meanwhile, each of the tRAS count circuits tCC_11 to tCC_2N may be disposed between through-silicon vias. For example, the 11-th tRAS count circuit tCC_11 included in the 11-th through-silicon via region TSV_R11 may be disposed between the 111-th through-silicon via TSV_111 and the 112-th through-silicon via TSV_112 in the first direction X. The 21-th tRAS count circuit tCC_21 included in the 11-th through-silicon via region TSV_R11 may be disposed between the 211-th through-silicon via TSV_211 and the 212-th through-silicon via TSV_212 in the first direction X.

Similarly, the 12-th tRAS count circuit tCC_12 included in the 12-th through-silicon via region TSV_R12 may be disposed between the 121-th through-silicon via TSV_121 and the 122-th through-silicon via TSV_122 in the first direction X. The 22-th tRAS count circuit tCC_22 included in the 12-th through-silicon via region TSV_R12 may be disposed between the 221-th through-silicon via TSV_221 and the 222-th through-silicon via TSV_222 in the first direction X.

In other words, the 1N-th tRAS count circuit tCC_1N included in the 1N-th through-silicon via region TSV_R1N may be disposed between the 1N1-th through-silicon via TSV_1N1 and the 1N2-th through-silicon via TSV_1N2 in the first direction X. The 2N-th tRAS count circuit tCC_2N included in the 1N-th through-silicon via region TSV_R1N may be disposed between the 2N1-th through-silicon via TSV_2N1 and the 2N2-th through-silicon via TSV_2N2 in the first direction X.

According to some implementations, the tRAS count circuit may be disposed between the plurality of through-silicon vias essentially required in the process of the semiconductor device, without securing an additional space for the tRAS count circuit, so it is possible to efficiently use the space inside the semiconductor device.

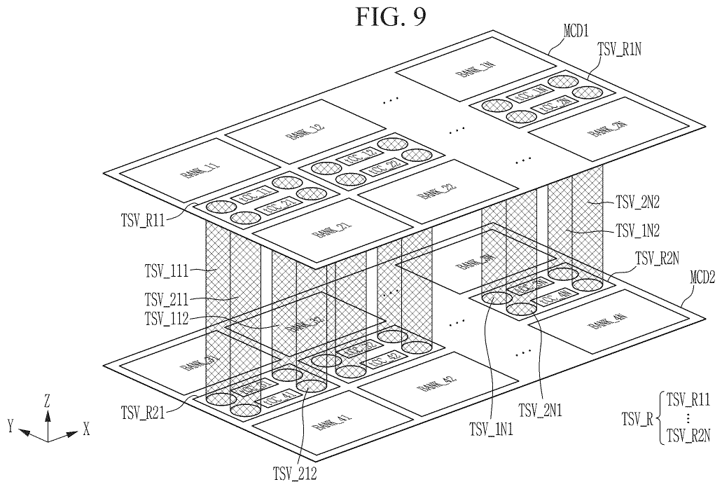

FIG. 9 is a drawing illustrating an example of a memory device according to some implementations. In FIG. 9, the memory device may include a second memory cell die MCD2 additionally stacked on the first memory cell die MCD1, shown in FIG. 8, in a third direction Z orthogonal to the first direction X and the second direction Y. The memory device shown in FIG. 9 may be, for example, a high bandwidth memory (HBM).

The second memory cell die MCD2 may include a plurality of banks of a third group that is arranged in the first direction X, and a plurality of banks of a fourth group that is spaced apart from the banks of the third group in the second direction Y and is arranged in the first direction X.

Specifically, the plurality of banks of the third group may include a 31-th bank BANK_31 to a 3N-th bank BANK_3N, and the plurality of banks of the fourth group may include a 41-th bank BANK_41 to a 4N-th bank BANK_4N.

The 31-th bank BANK_31 and the 41-th bank BANK_41 may be disposed at the same position in the first direction X so as to be spaced apart in the second direction Y, and the thirty-second bank BANK_32 and the 42-th bank BANK_42 may also be disposed at the same position in the first direction X so as to be spaced apart in the second direction Y. In other words, the 3N-th bank BANK_3N and the 4N-th bank BANK_4N may be disposed at the same position in the first direction X so as to be spaced apart in the second direction Y.

Further, the 11-th bank BANK_11 to the 1N-th bank BANK_1N of the first memory cell die MCD1 may be disposed so as to face the 31-th bank BANK_31 to the 3N-th bank BANK_3N of the second memory cell die MCD2 in the third direction Z, respectively. Similarly, the 21-th bank BANK_21 to the 2N-th bank BANK_2N of the first memory cell die MCD1 may be disposed so as to face the 41-th bank BANK_41 to the 4N-th bank BANK_4N of the second memory cell die MCD2 in the third direction Z, respectively.

All of the separation distance between the 31-th bank BANK_31 and the 41-th bank BANK_41, the separation distance between the thirty-second bank BANK_32 and the 42-th bank BANK_42, and the separation distance between the 3N-th bank BANK_3N and the 4N-th bank BANK_4N may be the same, and between banks corresponding to each other, a through-silicon via region TSV_R where a through-silicon via TSV is disposed may be disposed.

Specifically, a 21-th through-silicon via region TSV_R21 may be disposed in the separation region between the 31-th bank BANK_31 and the 41-th bank BANK_41 in the second direction Y. In other words, a 2N-th through-silicon via region TSV_R2N may be disposed in the separation region between the 3N-th bank BANK_3N and the 4N-th bank BANK_4N in the second direction Y.

Further, the 11-th through-silicon via region TSV_R11 to the 1N-th through-silicon via region TSV_R1N of the first memory cell die MCD1 may be disposed so as to face the 21-th through-silicon via region TSV_R21 to the 2N-th through-silicon via region TSV_R2N of the second memory cell die MCD2 in the third direction Z, respectively.

Each through-silicon via region TSV_R may include a plurality of through-silicon vias TSV_111 to TSV2N2. For example, the 21-th through-silicon via region TSV_R21 may include a 111-th through-silicon via TSV_111, a 112-th through-silicon via TSV_112, a 211-th through-silicon via TSV_211, and a 212-th through-silicon via TSV_212.

In other words, the 1N-th through-silicon via region TSV_R1N may include a 1N1-th through-silicon via TSV_1N1, a 1N2-th through-silicon via TSV_1N2, a 2N1-th through-silicon via TSV_2N1, and a 2N2-th through-silicon via TSV_2N2.

Each of the 111-th through-silicon via TSV_111, the 112-th through-silicon via TSV_112, the 211-th through-silicon via TSV_211, and the 212-th through-silicon via TSV_212 may be disposed such that it extends in the third direction Z so as to pass through the 11-th through-silicon via region TSV_R11 and the 21-th through-silicon via region TSV_R21 corresponding thereto.

In other words, each of the 1N1-th through-silicon via TSV_1N1, the 1N2-th through-silicon via TSV_1N2, the 2N1-th through-silicon via TSV_2N1, and the 2N2-th through-silicon via TSV_2N2 may be disposed such that it extends in the third direction Z so as to pass through the 1N-th through-silicon via region TSV_R1N and the 2N-th through-silicon via region TSV_R2N corresponding thereto.

The plurality of through-silicon vias included in each through-silicon via region TSV_R may transfer a signal which is input/output corresponding to banks adjacent to the through-silicon via region. For example, among the 111-th through-silicon via TSV_111, the 112-th through-silicon via TSV_112, the 211-th through-silicon via TSV_211, and the 212-th through-silicon via TSV_212 included in the 21-th through-silicon via region TSV_R21 positioned at the banks BANK_31 and BANK_41 disposed so as to be spaced apart in the second direction Y, two through-silicon vias (for example, TSV_112 and TSV212) may transfer a signal which is input/output corresponding to the banks BANK_31 and BANK_41. Among the 111-th through-silicon via TSV_111, the 112-th through-silicon via TSV_112, the 211-th through-silicon via TSV_211, and the 212-th through-silicon via TSV_212 included in the 11-th through-silicon via region TSV_R11 positioned at the banks BANK_11 and BANK_21 disposed so as to be spaced apart in the second direction Y, two different through-silicon vias (for example, TSV_111 and TSV211) may transfer a signal which is input/output corresponding to the banks BANK_11 and BANK_21.

Each through-silicon via region TSV_R may also include a plurality of tRAS count circuits tCC_11 to tCC_2N. For example, the 21-th through-silicon via region TSV_R21 may include a 31-th tRAS count circuit TCC_31 and a 41-th tRAS count circuit tCC_41. In other words, the 2N-th through-silicon via region TSV_R2N may include a 3N-th tRAS count circuit TCC_3N and a 4N-th tRAS count circuit tCC_4N.

The tRAS count circuits tCC_11 to tCC_2N included in each through-silicon via region TSV_R may perform a counting operation and a counting stop operation on the internal clock signal for the above-described tRAS section with respect to an adjacent bank. For example, the 31-th tRAS count circuit TCC_31 and the 41-th tRAS count circuit tCC_41 included in the 21-th through-silicon via region TSV_R21 may perform the counting operation and the counting stop operation, described above, on the 31-th bank BANK_31 and the 41-th bank BANK_41, respectively.

In other words, the 3N-th tRAS count circuit TCC_3N and the 4N-th tRAS count circuit tCC_4N included in the 2N-th through-silicon via region TSV_R2N may perform the counting operation and the counting stop operation, described above, on the 3N-th bank BANK_3N and the 4N-th bank BANK_4N adjacent thereto, respectively.

Meanwhile, each of the tRAS count circuits tCC_11 to tCC_2N may be disposed between through-silicon vias. For example, the 31-th tRAS count circuit TCC_31 included in the 21-th through-silicon via region TSV_R21 may be disposed between the 111-th through-silicon via TSV_111 and the 112-th through-silicon via TSV_112 in the first direction X. The 41-th tRAS count circuit tCC_41 included in the 21-th through-silicon via region TSV_R21 may be disposed between the 211-th through-silicon via TSV_211 and the 212-th through-silicon via TSV_212 in the first direction X.

In other words, the 3N-th tRAS count circuit TCC_3N included in the 2N-th through-silicon via region TSV_R2N may be disposed between the 1N1-th through-silicon via TSV_1N1 and the 1N2-th through-silicon via TSV_1N2 in the first direction X. The 4N-th tRAS count circuit tCC_4N included in the 2N-th through-silicon via region TSV_R2N may be disposed between the 2N1-th through-silicon via TSV_2N1 and the 2N2-th through-silicon via TSV_2N2 in the first direction X.

Each tRAS count circuit may be positioned adjacent to a through-silicon via for transferring signals which are input/output corresponding to an adjacent bank. For example, the 31-th tRAS count circuit TCC_31 included in the 21-th through-silicon via region TSV_R21 may be positioned adjacent to the 112-th through-silicon via TSV_112 for transferring signals which are input/output corresponding to the 31-th bank BANK_31.

As described above, the tRAS count circuit may be disposed between the plurality of through-silicon vias essentially required in the process of the semiconductor device, without securing an additional space for the tRAS count circuit, so it is possible to efficiently use the space inside the semiconductor device.

In particular, in a memory device which includes a larger number of banks by stacking a plurality of memory cell dies, such as a high bandwidth memory, the efficient use of the internal space of the semiconductor device can be increased.

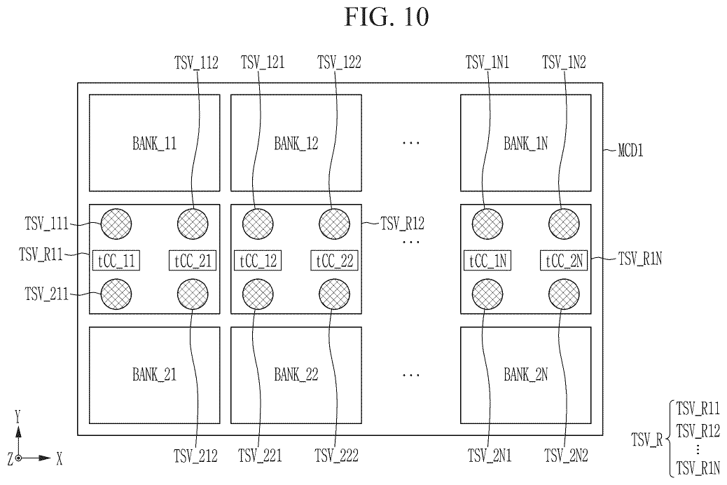

FIG. 10 is a drawing illustrating an example of a memory device according to some implementations. Hereinafter, a description will be made with a focus on the differences from the memory device shown in FIG. 8.

Unlike in FIG. 8, the 11-th tRAS count circuit tCC_11 included in the 11-th through-silicon via region TSV_R11 may be disposed between the 111-th through-silicon via TSV_111 and the 211-th through-silicon via TSV_211 in the second direction Y. The 21-th tRAS count circuit tCC_21 included in the 11-th through-silicon via region TSV_R11 may be disposed between the 112-th through-silicon via TSV_112 and the 212-th through-silicon via TSV_212 in the second direction Y.

Similarly, the 12-th tRAS count circuit tCC_12 included in the 12-th through-silicon via region TSV_R12 may be disposed between the 121-th through-silicon via TSV_121 and the 221-th through-silicon via TSV_221 in the second direction Y. The 22-th tRAS count circuit tCC_22 included in the 12-th through-silicon via region TSV_R12 may be disposed between the 122-th through-silicon via TSV_122 and the 222-th through-silicon via TSV_222 in the second direction Y.

In other words, the 1N-th tRAS count circuit tCC_1N included in the 1N-th through-silicon via region TSV_R1N may be disposed between the 1N1-th through-silicon via TSV_1N1 and the 2N1-th through-silicon via TSV_2N1 in the second direction Y. The 2N-th tRAS count circuit tCC_2N included in the 1N-th through-silicon via region TSV_R1N may be disposed between the 1N2-th through-silicon via TSV_1N2 and the 2N2-th through-silicon via TSV_2N2 in the second direction Y.

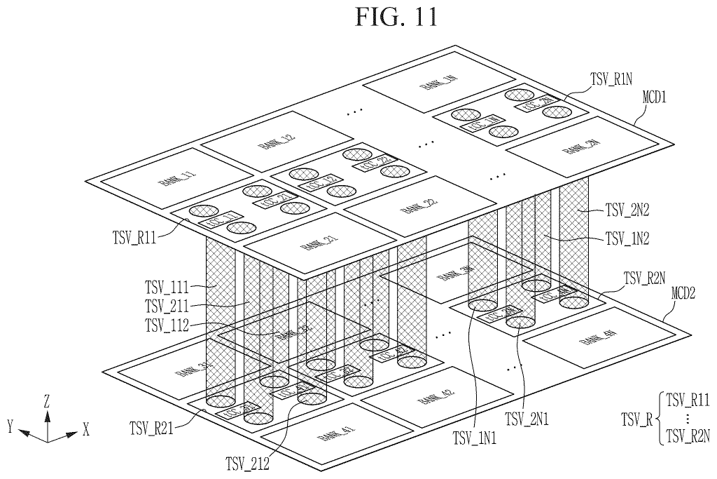

FIG. 11 is a drawing illustrating an example of a memory device according to some implementations. Hereinafter, a description will be made with a focus on the differences from the memory device shown in FIG. 9.

Unlike in FIG. 9, the 31-th tRAS count circuit TCC_31 included in the 21-th through-silicon via region TSV_R21 may be disposed between the 111-th through-silicon via TSV_111 and the 211-th through-silicon via TSV_211 in the second direction Y. The 41-th tRAS count circuit tCC_41 included in the 21-th through-silicon via region TSV_R21 may be disposed between the 112-th through-silicon via TSV_112 and the 212-th through-silicon via TSV_212 in the second direction Y.

In other words, the 3N-th tRAS count circuit tCC_3N included in the 2N-th through-silicon via region TSV_R2N may be disposed between the 1N1-th through-silicon via TSV_1N1 and the 2N1-th through-silicon via TSV_2N1 in the second direction Y. The 4N-th tRAS count circuit tCC_4N included in the 2N-th through-silicon via region TSV_R2N may be disposed between the 1N2-th through-silicon via TSV_1N2 and the 2N2-th through-silicon via TSV_2N2 in the second direction Y.

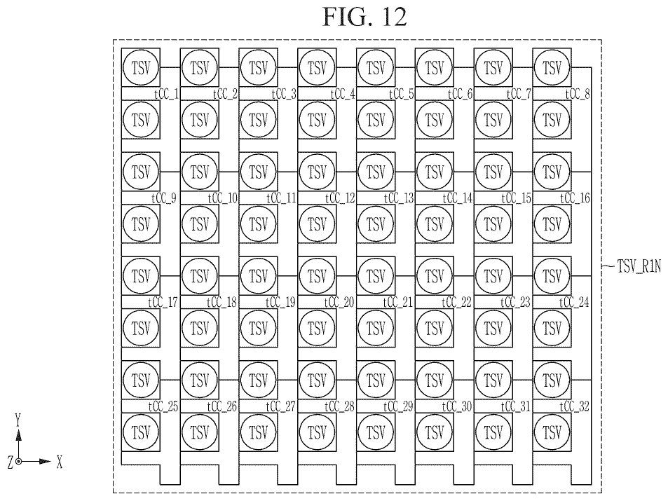

Meanwhile, although it is shown in FIGS. 8 to 11 that four through-silicon vias and two tRAS count circuits are included in each through-silicon via region, the exemplary embodiment is not necessarily limited thereto, and the numbers of through-silicon vias and tRAS count circuits which are included in each through-silicon via region may be changed at any time depending on exemplary embodiments. This will be described below with reference to FIG. 12.

FIG. 12 is a drawing illustrating an example of a memory device according to some implementations. In FIG. 12, the 1N-th through-silicon via region TSV_R1N may include 64 through-silicon vias TSV, and 32 count circuits including a first tRAS count circuit tCC_1 to a 32-th tRAS count circuit tCC_32. In this case, each of the first tRAS count circuit tCC_1 to the 32-th tRAS count circuit tCC_32 may be disposed between a plurality of through-silicon vias TSV.

Each of the first tRAS count circuit tCC_1 to the 32-th tRAS count circuit tCC_32 may be a count circuit corresponding to an adjacent bank, for example, as described with reference to FIGS. 8 to 11.

However, the present disclosure is not necessarily limited thereto, and each of the first tRAS count circuit tCC_1 to the 32-th tRAS count circuit tCC_32 may be a count circuit corresponding to a nonadjacent bank. For example, each of the first tRAS count circuit tCC_1 to the 32-th tRAS count circuit tCC_32 may be a count circuit corresponding to one of the plurality of banks included in the second memory cell die MCD2 shown in FIGS. 9 and 11.

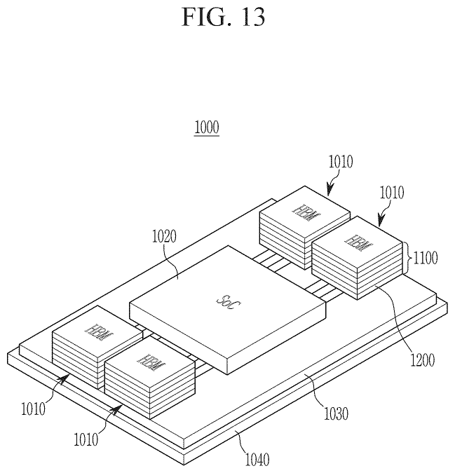

FIG. 13 is a perspective view illustrating an example of a semiconductor device according to some implementations. In FIG. 13, a semiconductor device 1000 may be a semiconductor package, and may be a memory module including at least one memory device 1010 and a system-on-chip (SoC) 1020 mounted on a package substrate 1040 such as a printed circuit board (PCB). In some exemplary embodiments, as the memory device 1010, the memory device described with reference to FIGS. 1 to 12 may be applied.

On the package substrate 1040, an interposer 1030 may be selectively further provided. The memory device 1010 may be formed as a chip-on-chip (CoC). The memory device 1010 may include a memory die 1100 including at least one core die stacked on a logic die 1200. The memory die 1100 and the logic die 1200 may be connected to each other by a through-silicon via.

In some implementations, the memory device 1010 may be a high bandwidth memory of 500 GB/sec to 1 TB/sec, or more.

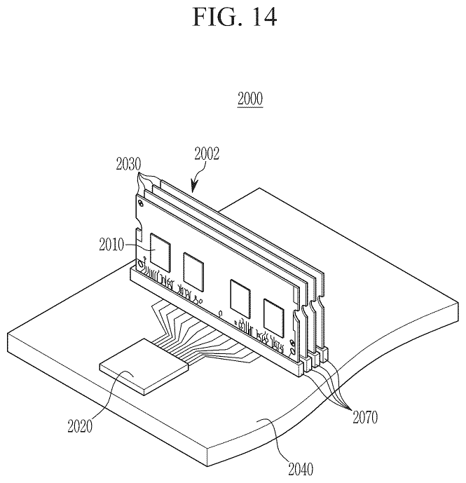

FIG. 14 is a perspective view illustrating an example of a semiconductor device according to some implementations. In FIG. 14, a semiconductor device 2000 may be a dual in-line memory module (DIMM) system which is made by mounting semiconductor chips on both surfaces of a printed circuit board, and may include a memory module 2002 including at least one PCB 2030, and a memory controller 2020. The memory controller 2020 may be mounted on a main board 2040, and the PCB 2030 may be electrically connected to the main board 2040 through a plurality of connection sockets.

The memory device 2010 may be formed as a chip-on-chip, and may be mounted on both surfaces of the PCB 2030. The memory controller 2020 and the memory device 2010 may be electrically connected through the PCB 2030 and a bus in the main board 2040. In some implementations, the memory device 2010 may include a stack structure of a memory die and a logic die. In some implementations, as the memory device 2010, the memory device described with reference to FIGS. 1 to 12 may be applied.

In some exemplary embodiments, the memory device 2010 may be a high bandwidth memory of 500 GB/sec to 1 TB/sec, or more.

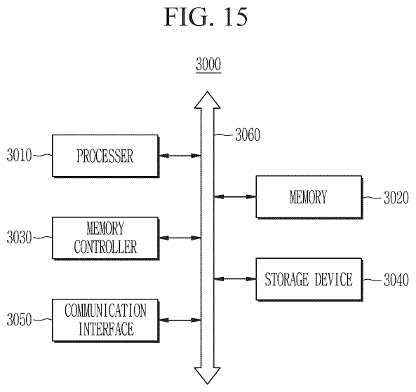

FIG. 15 is a schematic block diagram illustrating an example of a computing device according to some implementations. In FIG. 15, a computing device 3000 may include a processor 3010, a memory 3020, a memory controller 3030, a storage device 3040, a communication interface 3050, and a bus 3060. The computing device 3000 may further include other general-purpose constituent elements.

The processor 3010 may control the overall operation of each component of the computing device 3000. The processor 3010 may be implemented with at least one of various processing units, such as central processing units (CPUs), application processors (APs), and graphic processing units (GPUs).

The memory 3020 stores a variety of data and commands. The memory 3020 may be implemented with the memory device described with reference to FIGS. 1 to 12.

The memory controller 3030 may control transfer of data or command to the memory 3020 and from the memory 3020. In some implementations, the memory controller 3030 may be provided as a chip separate from the processor 3010. In some implementations, the memory controller 3030 may be provided as an internal component of the processor 3010.

The storage device 3040 may non-temporarily store programs and data. In some implementations, the storage device 3040 may be realized with a non-volatile memory.

The communication interface 3050 may support wired/wireless Internet communication of the computing device 3000. Also, the communication interface 3050 may support various communication methods other than Internet communication.

The bus 3060 may provide a communication function between the constituent elements of the computing device 3000. The bus 3060 may include at least one tangible bus according to a communication protocol between the constituent elements.

In some implementations, each constituent element or a combination of two or more constituent elements described with reference to FIGS. 1 to 15 may be realized with digital circuits, programmable or non-programmable logic devices or arrays, application specific integrated circuits (ASICs), etc.

While this disclosure contains many specific implementation details, these should not be construed as limitations on the scope of what may be claimed, equivalents thereof, as well as claims to be described later. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

What is claimed is:

1. A memory device comprising:
an active control circuit configured to generate an active progress signal based on an active signal;
a counter circuit configured to
receive an internal clock signal, the active progress signal, and internal clock signal information,
count the internal clock signal, and
output a counting completion signal based on the count of the internal clock signal, and based on the internal clock signal information; and
a counter block circuit configured to output, based on the counting completion signal, a counting stop signal.

2. The memory device of claim 1, further comprising:
a command generating circuit configured to generate an internal precharge signal based on an auto-precharge signal and the counting completion signal; and
a counter reset circuit configured to output a reset signal based on the internal precharge signal.

3. The memory device of claim 2, wherein the counter block circuit is configured to:
receive a subsequent active progress signal following the active progress signal; and
stop output of the counting stop signal based on the subsequent active progress signal.

4. The memory device of claim 1, wherein the counter circuit is configured to:
receive the active progress signal; and
count the internal clock signal based on the active progress signal having a second level that has transitioned from a first level that is lower than the second level.

5. The memory device of claim 1, wherein the counter circuit is configured to:
receive the counting stop signal having transitioned from a first level to a second level higher than the first level; and
stop the count of the internal clock based on the counting stop signal of the second level.

6. The memory device of claim 5, wherein the counter block circuit is configured to:
receive a subsequent active progress signal following the active progress signal; and
change the counting stop signal from the second level to the first level based on the subsequent active progress signal.

7. A memory device comprising:
a first memory bank disposed inside a first memory cell die;
a second memory bank disposed inside the first memory cell die, the second memory bank being spaced apart from the first memory bank in a first direction;
a plurality of through-silicon vias positioned inside the first memory cell die in a region between the first memory bank and the second memory bank; and
a first count circuit positioned among the plurality of through-silicon vias inside the first memory cell die,
wherein the first count circuit is configured to
receive a first active signal,
activate the first memory bank based on the first active signal,
receive an internal clock signal,
count the internal clock signal, and
block the internal clock signal based upon completion of the count of the internal clock signal.

8. The memory device of claim 7, further comprising a second count circuit positioned among the plurality of through-silicon vias,
wherein the second count circuit is configured to
receive a second active signal,
activate the second memory bank based on the second active signal,
receive a second internal clock signal,
count the second internal clock signal, and
block the second internal clock signal based upon completion of the count of the second internal clock signal.

9. The memory device of claim 8, wherein the first count circuit is positioned in a region adjacent to a first through-silicon via of the plurality of through-silicon vias connected to the first memory bank.

10. The memory device of claim 8,
wherein the plurality of through-silicon vias comprises:
a first through-silicon via;
a second through-silicon via spaced apart from the first through-silicon via in a second direction orthogonal to the first direction;
a third through-silicon via spaced apart from the first through-silicon via in the first direction; and
a fourth through-silicon via spaced apart from the second through-silicon via in the first direction, and
wherein the first count circuit is in a region spaced apart from the first through-silicon via and the second through-silicon via in the second direction.

11. The memory device of claim 10, wherein the second count circuit is in a region spaced apart from the third through-silicon via and the fourth through-silicon via in the second direction.

12. The memory device of claim 10, further comprising:
a third memory bank inside a second memory cell die stacked on the first memory cell die in a third direction orthogonal to the first direction and the second direction; and
a fourth memory bank inside the second memory cell die and spaced apart from the third memory bank in the first direction,
wherein the plurality of through-silicon vias are positioned in a region between the third memory bank and the fourth memory bank inside the second memory cell die.

13. The memory device of claim 12, further comprising:
a third count circuit positioned among the plurality of through-silicon vias inside the second memory cell die,
wherein the third count circuit is configured to
receive a third active signal,
activate the third memory bank based on the third active signal,
receive a third internal clock signal,
count the third internal clock signal, and
block the third internal clock signal based on completion of the count of the third internal clock signal; and
a fourth count circuit positioned among the plurality of through-silicon vias inside the second memory cell die,
wherein the fourth count circuit is configured to
receive a fourth active signal,
activate the fourth memory bank based on the fourth active signal,
receive a fourth internal clock signal,
count the fourth the internal clock signal, and
block the fourth internal clock signal based on completion of the count of the fourth internal clock signal.

14. The memory device of claim 13,
wherein the third count circuit is in a region spaced apart from the first through-silicon via and the second through-silicon via in the second direction, and
wherein the fourth count circuit is in a region spaced apart from the third through-silicon via and the fourth through-silicon via in the second direction.

15. The memory device of claim 7, wherein the first count circuit comprises:
an active control circuit configured to generate a first active progress signal based on the first active signal;
a counter circuit configured to
receive the internal clock signal, the first active progress signal, and internal clock signal information,
count the internal clock signal, and
output a counting completion signal based on the count of the internal clock signal and the internal clock signal information; and
a counter block circuit configured to output a counting stop signal based on the counting completion signal.

16. The memory device of claim 15, wherein the first count circuit further comprises:
a command generating circuit configured to generate an internal precharge signal based on an auto-precharge signal and the counting completion signal; and
a counter reset circuit configured to output a reset signal to reset the counter circuit based on the internal precharge signal.

17. A method for operating a memory device, the method comprising:
generating an active progress signal based on an active signal;
receiving an internal clock signal, the active progress signal, and internal clock signal information;
counting the internal clock signal;
outputting a counting completion signal based on a counting result of the internal clock signal and the internal clock signal information; and
outputting a counting stop signal, based on the counting completion signal, to stop the counting operation.

18. The method for operating the memory device according to claim 17, wherein counting the internal clock signal comprises:
receiving the active progress signal, wherein the active progress signal has transitioned from a first level to a second level higher than the first level; and
counting the internal clock signal based on the active progress signal at the second level.

19. The method for operating the memory device according to claim 17, wherein outputting the counting stop signal comprises outputting the counting stop signal based on the counting stop signal having transitioned from a first level to a second level higher than the first level in response to reception of the counting completion signal.

20. The method for operating the memory device according to claim 19, further comprising:
receiving a subsequent active progress signal following the active progress signal; and
changing the counting stop signal from the second level to the first level based on the subsequent active progress signal.
